(19) United States
(12) Patent Application Publication
(10) Pub. No.: US 2005/0179459 A1
(43) Pub. Date: Aug. 18, 2005

(54) Method and system for testing an electronic device

(75) Inventors: Lianrui Zhang, Plano, TX (US); Henry P. Largey, Wylie, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/780,247

(22) Filed: Feb. 17, 2004

(51) Int. Cl. G01R 31/02

(52) U.S. Cl. 324/763

(57) ABSTRACT

According to one embodiment of the invention, a method for testing a device is provided. The method includes testing an electronic device having a first operating frequency by a tester device having a second operating frequency. The method also includes determining, during the test, a frequency difference between the first operating frequency and the second operating frequency. The method also includes initiating an equalization of the first and the second operating frequencies using a signal indicative of the frequency difference.

### TECHNICAL FIELD OF THE INVENTION

This invention relates generally to electronics and more particularly to a method and system for testing an electronic device.

### BACKGROUND OF THE INVENTION

Electronic devices are commonly used to make electronic products. For example, integrated circuits (“IC”) are used to carry out certain functions of a cellular phone, a personal digital assistant (“PDA”), and a laptop computer. ICs are also used to control functions of traditionally mechanical devices, such as an automobile and an aircraft. To maintain a certain level of quality and reliability, these electronic devices generally undergo a testing process as a part of the manufacturing process.

In many cases, a testing procedure requires a tester device that is capable of evaluating the manufactured electronic device's performance. As a part of the evaluation, the tester device may be required to elicit and receive information from the DUT at appropriate time periods as a part of the test. These time periods may be determined using an operating frequency that is generated by an internal clock of a tester device.

In cases where the device under test (“DUT”) also has an operating frequency—and thus its own concept of time—the tester device may be required to perform oversampling to determine the appropriate time periods to elicit/receive information from the DUT. Because oversampling is a complicated process, the testing of the DUT having a clock may consume significant amounts of time and resources. The oversampling process may be further complicated by the drifting of the operating frequencies of the tester device and the DUT.

### SUMMARY OF THE INVENTION

According to one embodiment of the invention, a method for testing a device is provided. The method includes testing an electronic device having a first operating frequency by a tester device having a second operating frequency. The method also includes determining, during the test, a frequency difference between the first operating frequency and the second operating frequency. The method also includes initiating an equalization of the first and the second operating frequencies using a signal indicative of the frequency difference.

Some embodiments of the invention provide numerous technical advantages. Other embodiments may realize some, none, or all of these advantages. For example, according to one embodiment, the testing of an electronic device is improved by eliminating the need for oversampling. According to another embodiment, the accuracy of a testing procedure for an electronic device is increased by equalizing the operating frequencies of the tester device and the device under test (“DUT”). According to another embodiment, existing tester devices may be economically modified to eliminate the need for oversampling.

Other advantages may be readily ascertainable by those skilled in the art.

### BRIEF DESCRIPTION OF THE DRAWINGS

Reference is now made to the following description taken in conjunction with the accompanying drawings, wherein like reference numbers represent like parts, in which:

FIG. 1 is a schematic diagram illustrating one embodiment of a testing environment;

FIGS. 2A-2B are schematic diagrams each illustrating one embodiment of the testing system shown in FIG. 1;

FIG. 2C is a circuit diagram illustrating one embodiment of the testing system shown in FIG. 1; and

FIG. 3 is a block diagram illustrating one embodiment of a method for testing an electronic device.

### DETAILED DESCRIPTION OF EXAMPLE EMBODIMENTS OF THE INVENTION

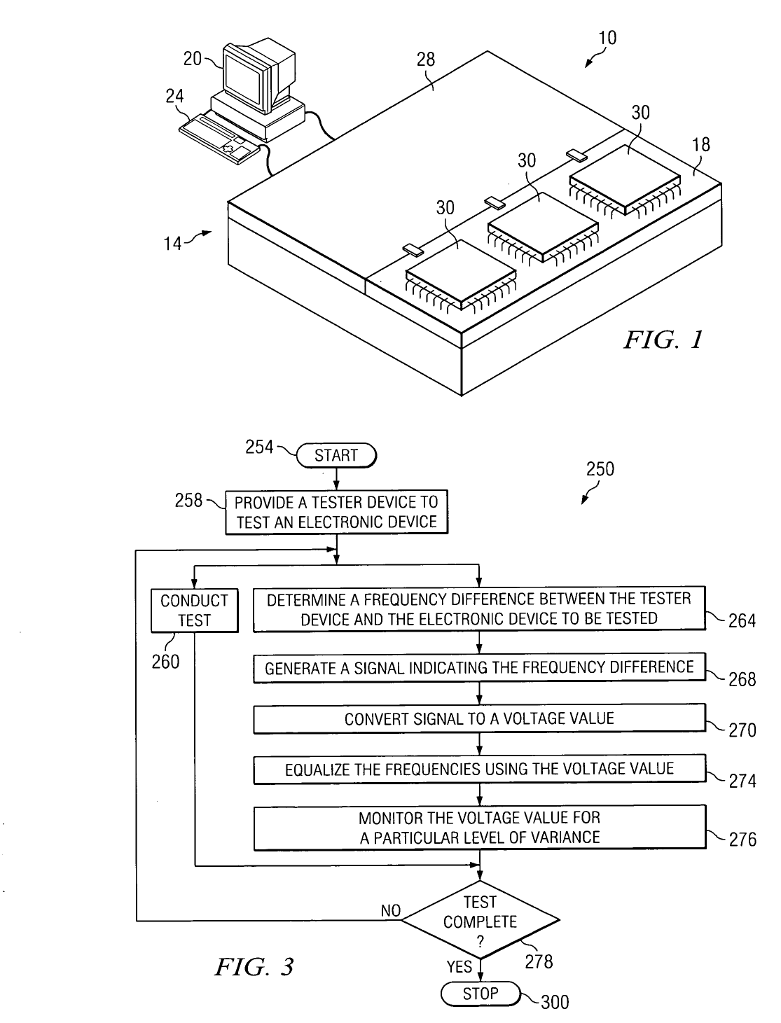

Embodiments of the invention are best understood by referring to FIGS. 1 through 3 of the drawings, like numerals being used for like and corresponding parts of the various drawings.

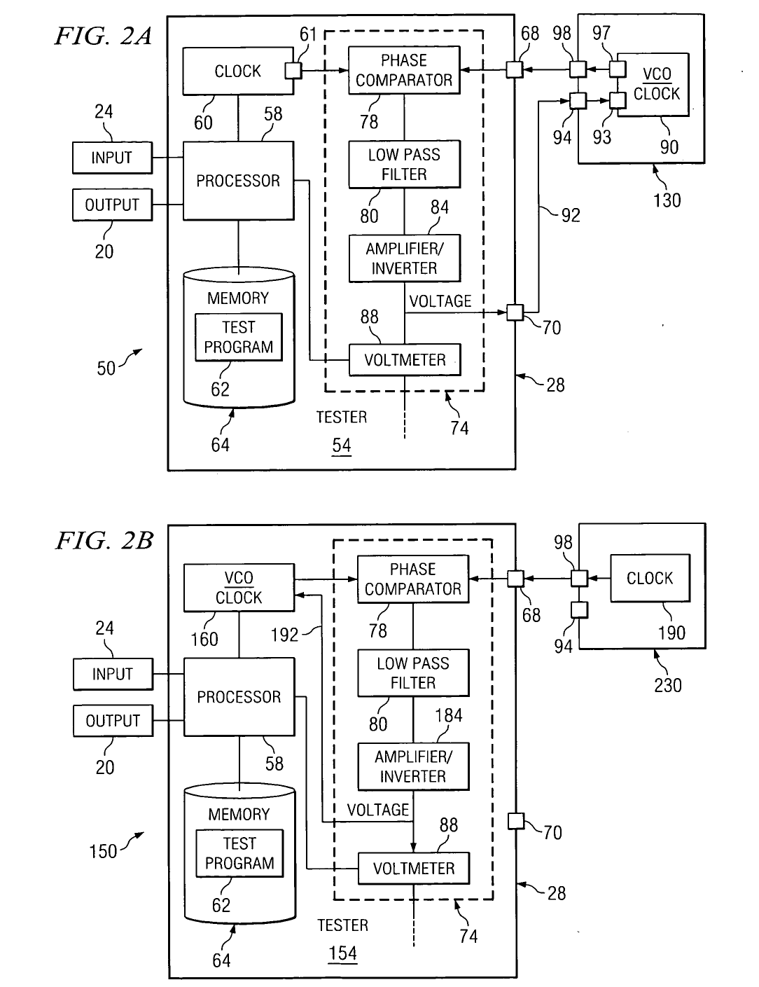

FIG. 1 is a schematic diagram illustrating one embodiment of a device testing environment 10 for conducting one or more tests as a part of a manufacturing process. Environment 10 includes a tester device 14, a housing 28, a platform 18, an output device 20, an input device 24 and one or more devices under test (“DUT”) 30. Tester device 14 is encased in housing 28 and coupled to platform 18, output device 20, and input device 24, in this embodiment. DUTs 30 are coupled to tester device 14 through platform 18. Tester device 14 is operable to elicit and receive from DUT 30 certain information in a particular sequence to determine whether DUT 30 meets a particular performance standard. Additional details concerning a testing procedure are described below in conjunction with FIG. 2A. An example of tester device 14 is TERADYNE A580, available from Teradyne Inc; however, any suitable tester device may be used.

Platform 18 may be any type of receiving device, such as a plug-in board, that is configured to receive one or more DUT 30, and to couple DUT 30 to tester 14. For example, where DUT 30 is an integrated circuit (“IC”), platform 18 may be a board having apertures that are positioned to receive the pins of IC 30 and electrically couple the pins to tester 14 through the apertures. Output device 20 may be any device that is operable to communicate any information to a user of tester device 14. An example of output device 20 is a computer monitor. Input device 24 may be any input device that is operable to allow a user of tester device 14 to provide input, such as testing parameters or commands, into tester device 14. An example of input device 24 is a computer keyboard.

DUT 30 may be any electronic device that is operable to perform a particular function, such as executing one or more logical functions, or to store data. Examples of DUT 30 include an integrated circuit (“IC”) that is used in a cellular phone, a broadband device, a voiceband device, and a radio frequency device; however, any suitable electronic device that may undergo a test may be DUT 30.

A tester device, such as tester device 14, generally has an internal clock that sets an operating frequency of the tester device. This operating frequency may be used to determine the appropriate time periods in which the tester device elicits and/or receives information from a DUT to test the DUT. In cases where the DUT also has an internal clock—and thus has its own operating frequency and concept of time—the tester device may be required to perform oversampling to reconcile the two different operating frequencies in order to determine the appropriate time windows to elicit/receive information from the DUT. Oversampling is generally a complicated process. The complexity of oversampling may increase when the respective clocks of the tester device and the DUT start to independently drift. Thus, the testing of the DUT having its own clock may consume significant amounts of time and resources due to the oversampling process. Further, because oversampling results in particular windows of time during which information from the DUT may be elicited/received—not particular time periods—testing errors commonly referred to as “spectrum spreading” may occur.

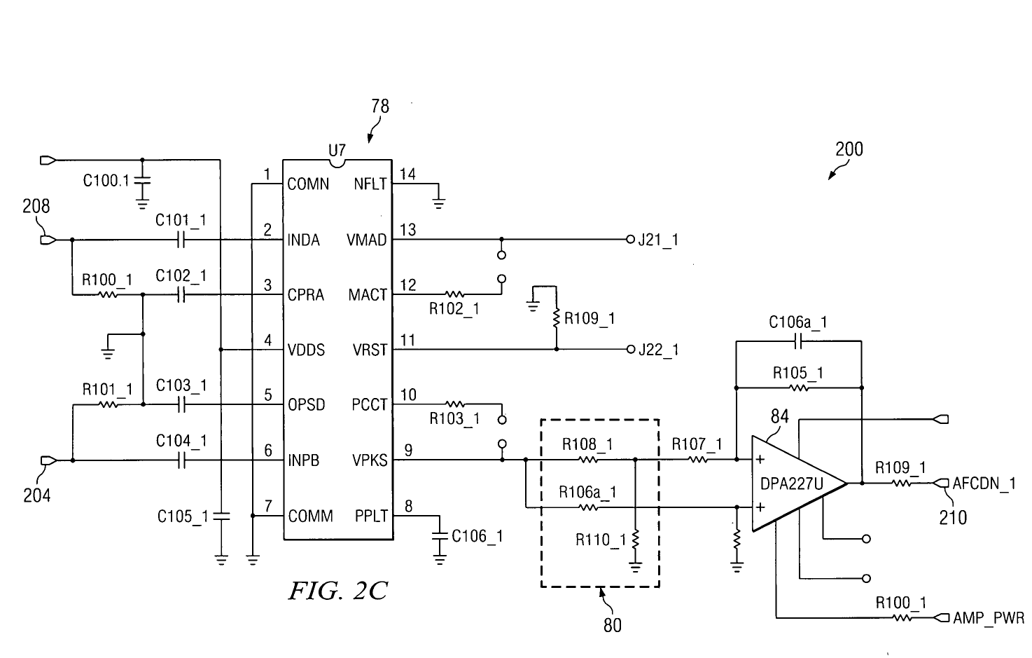

According to one embodiment of the present invention, a method and system for testing an electronic device are provided. In one embodiment, the operating frequencies of a tester device and a device under test (“DUT”) are equalized by implementing a phase lock loop in a testing environment, which eliminates the need for oversampling. In another embodiment, an existing tester devices and/or DUT may be modified to include some or all components of a phase lock loop. Additional details of example embodiments of the invention are described below in greater detail in conjunction with FIGS. 2A-3.

FIG. 2A is a block diagram illustrating one embodiment of a testing system 50 that may be used in testing environment 10 of FIG. 1. System 50 comprises a DUT 130 and a tester device 54. DUT 130 comprises a clock 90, an input pin 94 and an output pin 98. Clock 90 comprises a clock input 93 and a clock output 97 that are coupled to pins 94 and 98, respectively. Clock 90 is operable to provide an operating frequency for DUT 130. FIG. 2A shows one embodiment of the invention where a frequency of clock 90 is adjusted to substantially equal a frequency of a clock of tester device 54. As such, in one embodiment, clock 90 may be a voltage controlled oscillator that is operable to receive a signal and adjust its own operating frequency using the signal; however, clock 90 may be any type of clock that may receive a signal and adjust its own frequency using the signal.

Tester device 54 comprises a processor 58, a clock 60, a memory 64, an input pin 68, an output pin 70, a phase lock loop unit 74, output unit 20, and input unit 24. Clock 60 comprises a clock output 61 that is coupled to phase lock loop unit 74. Processor 58 is coupled to output unit 20, input unit 24, clock 60, memory 64, and phase lock loop unit 74, as shown in FIG. 2A. Processor 58 is operable to execute the logic of a testing program 62 that may be stored in memory 64 to test DUT 130. Processor 58 may be operable to access memory 64 to retrieve and/or store data associated with testing program 64. In one embodiment, a test may involve measuring a cellular phone transmitter output power spectrum. The DUT output may be digitized and used in conjunction with fast Fourier Transform to determine the output power spectrum distribution. In one embodiment, evaluating whether an IC that has been manufactured can perform according to a particular specification prior to installation into a final product, such as a cellular phone, laptop computer, or other end products, would be considered a “test.” In another embodiment, evaluation of an IC as a part of repair would be considered a “test.”

Referring again to FIG. 2A, clock 60 is operable to provide an operating frequency for tester device 54. Working in conjunction with clock 60, memory 64, output unit 20, and input unit 24, processor 58 is operable to execute testing program 62 and determine whether DUT 130 meets a particular performance standard that may be established depending on the requirements placed on DUT 130. There are numerous performance standards to which DUT 130 may be measured. Examples of performance standards include power spectrum and spur, DUT clock frequency tuning range, radio frequency (RF) output harmonic distortion and intermodulation, cellular phone or bluetooth receiver bit error rate, receiver gain and phase, phase trajectory, error vector magnitude, and communications device constellation and eye diagrams; however, any other suitable performance standard may be used to test DUT 130.

According to some embodiments of the invention, phase lock loop unit 74 is provided to equalize the operating frequencies of clocks 60 and 90 during a test. Equalizing the operating frequencies of clocks 60 and 90 is advantageous in some embodiments of the invention because, with both clocks 60 and 90 operating at substantially the same frequency, the appropriate time periods for communication between DUT 130 and tester device 54 may be established without conducting oversampling. Further, the established time periods for communication between DUT 130 and tester device 54 are not time windows, which may eliminate spectrum spreading.

In one embodiment, phase lock loop unit 74 operates as a phase lock loop circuit that is operable to adjust at least one of the operating frequencies to make all the operating frequencies equal; however, any device for equalizing frequencies may be used. In one embodiment, phase lock loop unit 74 comprises a phase comparator 78, a filter 80, and an amplifier 84. Phase comparator 78 is coupled to clock 60, input pin 68, and filter 80. Filter 80 is coupled to amplifier 84, and amplifier 84 is coupled to output pin 70. In one embodiment, as shown in FIG. 2A, a volt meter 88 may also be included in unit 74. In such an embodiment, volt meter 88 is coupled to amplifier 84 and processor 58. In one embodiment, when tester device 54 is coupled to DUT 130 for testing, pins 68 and 70 are respectively coupled to pins 98 and 94. As shown in FIG. 2A, pins 70 and 94 form a path 92, which, in one embodiment, may operate as a conduit for sending signals that may be used to adjust the frequency of clock 90.

Phase comparator 78 is operable to receive operating frequencies from clock 60 of tester device 54 and clock 90 of DUT 130, and to determine a frequency difference from the two received frequencies. After determining a frequency difference, phrase comparator 78 is operable to transmit a signal indicating the frequency difference to filter 80. In one embodiment, the signal may be a series of pulses. Filter 80 is operable to receive the pulses transmitted from phase comparator 78 and convert the received pulses into an average of pulse widths. In one embodiment, filter 80 is also operable to filter out certain pulses that exceed a predetermined threshold. Amplifier 84 is operable to receive the signal indicating the average pulse width and convert the signal to a voltage value. In one embodiment, volt meter 88 is operable to receive the voltage value and monitor any variance in the voltage values generated by amplifier 84.

In operation, phase comparator 78 receives the operating frequencies of tester device 54 and DUT 130 from their respective clocks 60 and 90. After determining a frequency difference between the two received operating frequencies, phase comparator 78 transmits a series of pulses indicating the determined frequency difference to filter 80. Filter 80 receives the pulses and determines an average pulse width based on the received series of pulses. Filter 80 then sends a signal indicating the determined average pulse width to amplifier 84, which in turn converts the received signal into a voltage value. Amplifier 84 transmits the voltage value to clock 90 through output pin 70, path 92, and input pin 94 of the DUT 130. In one embodiment where clock 90 is a voltage controlled oscillator, clock 90 can adjust its operating frequency value to equal that of clock 60 using the voltage value, which indicates the voltage difference between the operating frequency of clock 60 and the previous operating frequency of clock 90. For example, if the operating frequency of clock 90 is lower than that of clock 60, then clock 90 may increase its operating frequency by a margin indicated by the received value so that the frequencies of clocks 60 and 90 are substantially equal.

In one embodiment where volt meter 88 is used to monitor the voltage values transmitted from amplifier 84, volt meter 88 may monitor the consistency of the voltage values received from amplifier 84. Volt meter 88 then sends the data to processor 58. If the data concerning the voltage values from volt meter 88 indicate that the variance of the voltage values exceeds a predetermined threshold, then processor 58 may determine that DUT 130 is unstable, and thus may fail DUT 130.

FIG. 2B is a schematic diagram illustrating one embodiment of a testing system 150 that may be used in testing environment 10 shown in FIG. 1. Only the portions of FIG. 2B that are different from system 50 of FIG. 2A are described below. System 150 comprises a tester device 154 coupled to a DUT 230. DUT 230 comprises a clock 190 having an operating frequency. As with tester device 54 of FIG. 2A, tester device 154 comprises processor 58 coupled to memory 64, output unit 20, and input unit 24. Tester device 154 also comprises a clock 160 and a path 192 that couples amplifier 84 of unit 74 to clock 160. Because system 150 shows one embodiment of the invention where a frequency of tester device 154 is adjusted to substantially equal a frequency of DUT 230, in one embodiment, clock 160 is operable to adjust its operating frequency using a voltage value. For example, in one embodiment, clock 160 may be a voltage controlled oscillator operable to receive a voltage value and adjust its own frequency; however, clock 160 may be any type of clock that may receive a signal and adjust its own frequency using the signal. As shown in FIG. 2B, path 192 carries the voltage value from amplifier 84 to clock 160.

In operation, phase comparator 78 receives the operating frequencies of tester device 154 and DUT 230 from their respective clocks 160 and 190. After determining a frequency difference between the two received operating frequencies, phase comparator 78 transmits a series of pulses indicating the determined frequency difference to filter 80. Filter 80 receives the pulses and determines an average pulse width based on the received series of pulses. Filter 80 then sends a signal indicating the determined average pulse width to amplifier 84, which in turn converts the received signal into a voltage value. Amplifier 84 transmits the voltage value to clock 160 over path 192. Using the received voltage value, clock 160 adjusts its own operating frequency to substantially equal that of 190. For example, if the operating frequency of clock 190 is lower than that of clock 160, then clock 160 may decrease its operating frequency by a margin indicated by the received value so that the frequencies of clocks 160 and 190 are substantially equal.

In one embodiment, phase lock loop unit 74 is positioned inside housing 28 of tester device 54 and permanently coupled to tester device 54. “Permanently coupled” refers to any coupling where removal is not intended. For example, unit 74 may be on a circuit board (not explicitly shown) separate from a circuit board (not explicitly shown) of tester device 54 but may be permanently coupled to the circuit board of tester device 54 by plugging into a socket (not explicitly shown) that is soldered onto the circuit board of tester device 54. In some embodiments, some or all of the components of unit 74 may be positioned in tester device 54, DUT 130, and/or in a device independent from tester device 54 and DUT 130. For example, phase comparator 78 may be manufactured as a part of DUT 130. In another example, phase lock loop unit 74 may be positioned in DUT 130. If such an embodiment were implemented using system 50 of FIG. 2A, the operating frequency of clock 60 may be sent to phase comparator 78 through pins 68 and 98. Also, the output from volt meter 88 may be sent to processor 58 through pins 94 and 70. In another example, referring back to FIG. 2B, the whole or any part of phase lock loop unit 74 may form an independent unit and/or positioned in DUT 230. In such an embodiment, the operating frequency of clock 160 may be sent to phase comparator 78 through pins 68 and 98. Also, the output from amplifier 84 and volt meter 88 may be sent to clock 160 and processor 58, respectively, through pins 94 and 70. One skilled in the art may determine other ways to implement phase lock loop unit 74.

FIG. 2C is a circuit diagram 200 illustrating one embodiment of phase lock loop unit 74, as shown in FIGS. 2A and 2B. As shown in FIG. 2C, phase comparator 78, filter 80, and amplifier 84 of unit 74 are identified. Diagram 200 also identifies nodes 204 and 208 where operating frequencies of a tester device and a DUT may be inputted. Either nodes 204 or 208 may be used as an input for a tester device, such as devices 54 and 154, or a DUT, such as DUT 130 and 230. Diagram 200 also identifies a voltage out node 210, which may be coupled to a clock to be adjusted, such as clocks 90 and 160. In some embodiments, voltage out node 210 may also be coupled to volt meter 88 shown in FIGS. 2A and 2B. Circuit diagram 200 of FIG. 2C merely represents one way of implementing some embodiments of the invention; one skilled in the art may determine other methods of implementation.

FIG. 3 is a block diagram illustrating one embodiment of a method 250 for testing an electronic device. Method 250 may be implemented using systems 50 or 150 described in FIGS. 2A-2C. As an example, method 250 is described using the components of system 50; however, other appropriate components may be used to implement method 250. Method 250 starts at step 254. At step 258, a tester device, such as a tester device 54 shown in FIG. 2A, is provided to test an electronic device, such as DUT 130. An example of DUT 130 is an IC. At step 260, a test designed to determine whether DUT 130 meets a particular performance standard is conducted. At step 264, a frequency difference between tester device 54 and DUT 130 is determined. The frequency difference may be determined using phase comparator 78, in one embodiment. At step 268, a signal indicating the determined frequency difference is generated at filter 80. An example of the signal is a series of pulses. At step 270, the signal of step 268 is converted to a voltage value. At step 274, the operating frequencies of tester device 54 and DUT 130 are equalized. In one embodiment, the frequencies are equalized using the voltage value generated at step 270. In one embodiment of step 274, the operating frequency of DUT 130 is adjusted to substantially equal to the operating frequency of tester device 54. In another embodiment, as shown in FIG. 2B, the operating frequency of tester device 154 is adjusted to substantially equal the operating frequency of DUT 230.

At step 276, the voltage value is compared to a previously generated voltage value to determine whether the level of voltage value variance exceeds a particular level. In some embodiments, step 276 may be omitted. If the level of variance exceeds the particular threshold, then tester device 54 may fail DUT 130 as being unstable. At decision step 278, whether the test is completed is determined. If “no,” then method 250 returns to steps 260 and 264. If “yes,” then method 250 stops at step 300. As shown in FIG. 3, in one embodiment, steps 260, 264, 268, 270, 274, 276, and 278 may be repeated until the test is complete.

Although some embodiments of the present invention have been described in detail, it should be understood that various changes, substitutions, and alterations can be made hereto without departing from the spirit and scope of the invention as defined by the appended claims.

1. A system for testing an electronic device including a first clock having a first frequency, the system comprising:
a tester device including a housing, a clock input, and a second clock having a second frequency positioned in the housing, the tester device operable to electrically engage the first clock using the clock input and to determine that the electronic device meets a particular performance standard;
a phase comparator positioned in the housing and coupled to the second clock and the clock input, the phase comparator operable to determine a frequency difference between the first and the second frequencies;
a filter positioned in the housing and coupled to the phase comparator, the filter operable to generate a signal indicative of the frequency difference based on the determined frequency difference; and
an amplifier positioned in the housing and coupled to the filter, the amplifier operable to generate a voltage value indicative of the frequency difference based on the generated signal.

2. The system of claim 1, wherein the tester device further comprises a clock output coupled to the amplifier, the clock output operable to electrically engage the first clock, and wherein the amplifier is operable to transmit the voltage value to the first clock.

3. The system of claim 1, wherein the amplifier is operable to transmit the voltage value to the second clock, and wherein the second clock is a voltage controlled oscillator amplifier operable to receive the voltage value from the amplifier and adjust the second frequency to a new frequency that is substantially equal to the first frequency.

4. The system of claim 1, wherein the amplifier is coupled to a volt meter operable to indicate any change to the voltage value from a previous voltage value.

5. A method for testing a device, comprising:
testing an electronic device having a first operating frequency by a tester device having a second frequency;
during the testing, repeatedly determining any frequency difference between the first operating frequency and the second operating frequency; and
for each determination of the frequency difference, generating a voltage value indicative of the frequency difference and equalizing the first and the second operating frequencies using the voltage value.

6. The method of claim 5, wherein the equalizing comprises adjusting the first operating frequency by the frequency difference indicated by the voltage value.

7. The method of claim 5, wherein the equalizing comprises adjusting the second operating frequency by the frequency difference indicated by the voltage value.

8. The method of claim 5, and further comprising:
determining that a level of change in the voltage value compared to a previously generated voltage value exceeds a predetermined level;
indicating that the electronic device does not meet a particular performance standard.

9. The method of claim 5, wherein the electronic device is an integrated circuit, and the testing is conducted prior to an installation of the integrated circuit into a final product.

10. The method of claim 5, wherein determining any frequency difference comprises determining any frequency difference using a phase comparator permanently positioned in the electronic device.

11. The method of claim 5, wherein determining any frequency difference comprises determining any frequency difference using a phase comparator permanently positioned in the tester device.

12. The method of claim 5, wherein testing comprises performing a diagnostic procedure prior to an installation of the electronic device in a final product.

13. A method for testing a device, comprising:
testing an electronic device having a first operating frequency by a tester device having a second operating frequency;
during the test, determining a frequency difference between the first operating frequency and the second operating frequency; and
initiating an equalization of the first and the second operating frequencies using a signal indicative of the frequency difference.

14. The method of claim 13, and further comprising generating a voltage value indicative of the frequency difference, wherein the voltage value is used as the signal.

15. The method of claim 13, wherein the acts of determining a frequency difference and initiating an equalization are performed using the tester device.

16. The method of claim 13, wherein initiating the equalization comprises adjusting the first operating frequency by the frequency difference indicated by the signal.

17. The method of claim 13, wherein initiating the equalization comprises:
transmitting the signal to the electronic device; and
adjusting the second operating frequency by the frequency difference indicated by the signal.

18. The method of claim 13, wherein the signal is a voltage value, and further comprising:
determining that a level of change in the voltage value compared to a previously generated voltage value exceeds a predetermined level; and
indicating that the electronic device does not meet a predetermined performance standard.

19. The method of claim 13, wherein determining the frequency difference is performed using a phase comparator permanently coupled to the tester device.

20. The method of claim 13, wherein determining the frequency difference is performed using a phase lock loop circuit positioned in the tester device.
